(19) United States
(12) Patent Application Publication
(10) Pub. No.: US 2012/0024370 A1
(43) Pub. Date: Feb. 2, 2012

(54) Wafer Type Solar Cell and Method for Manufacturing the Same

(76) Inventor: Jung Hyun LEE, Suwon-si (KR)

(21) Appl. No.: 13/193,098

(22) Filed: Jul. 28, 2011

(30) Foreign Application Priority Data
Jul. 28, 2010 (KR) 10-2010-0072672

(51) Int. Cl. H01L 31/02; H01L 31/18; H01L 31/0224

(52) U.S. Cl. 136/256; 438/72; 438/71; 257/E31.13; 257/E31.119

(57) ABSTRACT

Disclosed is a wafer type solar cell and a method for manufacturing the same, which facilitates to enhance hole-collecting efficiency, and to improve cell efficiency by preventing transmittance of solar ray from being lowered, the wafer type solar cell comprising a first semiconductor layer of a semiconductor wafer; a second semiconductor layer doped with P-type dopant, wherein the second semiconductor layer is formed on one surface of the first semiconductor layer, on which solar ray is incident; a third semiconductor layer doped with N-type dopant, wherein the third semiconductor layer is formed on the other surface of the first semiconductor layer; a first passivation layer on the second semiconductor layer; a second passivation layer on the third semiconductor layer; a first electrode connected with the second semiconductor layer; and a second electrode connected with the third semiconductor layer.

### CROSS REFERENCE TO RELATED APPLICATIONS

This application claims the benefit of the Korean Patent Application No. P2010-0072672, filed on Jul. 28, 2010, which is hereby incorporated by reference as if fully set forth herein.

### BACKGROUND OF THE INVENTION

1. Field of the Invention

The present invention relates to a solar cell, and more particularly, to a wafer type solar cell.

2. Discussion of the Related Art

A solar cell with a property of semiconductor converts a light energy into an electric energy.

The solar cell is formed in a PN junction structure where a positive (P)-type semiconductor makes a junction with a negative (N)-type semiconductor. When a solar ray is incident on the solar cell with the PN junction structure, holes (+) and electrons (−) are generated in the semiconductor owing to the energy of the solar ray. By an electric field generated in a PN junction area, the holes (+) are drifted toward the P-type semiconductor and the electrons (−) are drifted toward the N-type semiconductor, whereby an electric power is produced with an occurrence of electric potential.

The solar cell can be largely classified into a wafer type solar cell and a thin film type solar cell.

The thin film type solar cell is manufactured by forming a semiconductor in type of a thin film on a glass substrate. The wafer type solar cell uses a wafer made of a semiconductor material such as silicon.

In case of the wafer type solar cell, it is difficult to realize a small thickness. In addition, the wafer type solar cell uses a high-priced semiconductor substrate, whereby its manufacturing cost is increased. However, with respect to efficiency, the wafer type solar cell is better than the thin film type solar cell.

Hereinafter, a related art wafer type solar cell will be described with reference to the accompanying drawings.

FIG. 1 is a cross section view illustrating a related art wafer type solar cell.

As shown in FIG. 1, the related art wafer type solar cell includes a P-type semiconductor layer 10, an N-type semiconductor layer 20, a reflection-preventing layer 30, a front electrode 40, a P⁺-type semiconductor layer 50, and a rear electrode 60.

A PN junction structure of the solar cell is formed by the P-type semiconductor layer 10, and the N-type semiconductor 20 on the P-type semiconductor layer 10.

The reflection-preventing layer 30 is formed on an upper surface of the N-type semiconductor layer 200, wherein the reflection-preventing layer 30 prevents incident solar rays from being reflected.

The P⁺-type semiconductor layer 50 is formed on a lower surface of the P-type semiconductor layer 10, wherein the P⁺-type semiconductor layer 50 prevents carrier extinction by recombination.

The front electrode 40 is formed from the upper surface of the reflection-preventing layer 30 to the N-type semiconductor layer 20. The rear electrode 60 is formed on a lower surface of the P⁺-type semiconductor layer 50.

As the solar ray is incident on the related art wafer type solar cell, electron and hole are generated, the generated electron is drifted to the front electrode 40 via the N-type semiconductor layer 20, and the generated hole is drifted to the rear electrode 60 via the P⁺-type semiconductor layer 50.

However, the related art wafer type solar cell has the following disadvantages.

Generally, a drift mobility of the hole is less than a drift mobility of the electron. Thus, in order to maximize the efficiency in collection of the hole, the P⁺-type semiconductor layer is provided adjacent to the solar ray incidence face, preferably. However, in case of the related art wafer type solar cell shown in FIG. 1, the P⁺-type semiconductor layer 50 is provided in an opposite surface to the solar ray incidence face, thereby causing the deteriorated efficiency in collection of the hole.

This problem is derived from the P⁺-type semiconductor layer 50 which is formed by the use of material for the rear electrode 60. That is, in case of the related art, a rear electrode material of aluminum (Al) is coated onto one surface of the P-type semiconductor layer 10, and then is heat-treated at a high temperature, whereby the P⁺-type semiconductor layer 50 is formed by permeation of aluminum (Al) into the one surface of the P-type semiconductor layer 10, and the rear electrode 60 is formed by the remaining aluminum (Al).

In order to form the P⁺-type semiconductor layer 50 on entire portions of one surface of the P-type semiconductor layer 10, a heat treatment has to be carried out after coating aluminum (Al) for the rear electrode 60 onto the entire portions of one surface of the P-type semiconductor layer 10. In this case, transmittance of solar ray is deteriorated due to aluminum (Al), if aluminum (Al) is coated onto the entire surface of the solar ray incidence face. In this reason, aluminum (Al) should be coated onto the opposite surface to the solar ray incidence face. Thus, the P⁺-type semiconductor layer 50 is formed on the opposite surface to the solar ray incidence face, whereby hole-collecting efficiency is deteriorated.

### SUMMARY OF THE INVENTION

Accordingly, the present invention is directed to a wafer type solar cell and a method for manufacturing the same that substantially obviates one or more problems due to limitations and disadvantages of the related art.

An object of the present invention is to provide a wafer type solar cell and a method for manufacturing the same, which facilitates to enhance hole-collecting efficiency, and to improve cell efficiency by preventing transmittance of the solar rays from being lowered.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a wafer type solar cell comprising: a first semiconductor layer of a semiconductor wafer; a second semiconductor layer doped with P-type dopant, wherein the second semiconductor layer is formed on one surface of the first semiconductor layer, on which solar rays are incident; a third semiconductor layer doped with N-type dopant, wherein the third semiconductor layer is formed on the other surface of the first semiconductor layer; a first passivation layer on the second semiconductor layer; a second passivation layer on the third semiconductor layer; a first electrode connected with the second semiconductor layer; and a second electrode connected with the third semiconductor layer.

In another aspect of the present invention, there is provided a method for manufacturing a wafer type solar cell comprising: preparing a semiconductor wafer; forming a second semiconductor layer by doping one surface of the semiconductor wafer with P-type dopant, and forming a third semiconductor layer by doping the other surface of the semiconductor wafer with N-type dopant; forming a first passivation layer on the second semiconductor layer; forming a second passivation layer on the third semiconductor layer; forming a first electrode connected with the second semiconductor layer; and forming a second electrode connected with the third semiconductor layer.

In another aspect of the present invention, there is provided A method for manufacturing a wafer type solar cell comprising: preparing a semiconductor wafer; forming a second passivation layer on a lower surface of the semiconductor wafer; forming a second contact portion in the second passivation layer; forming a second semiconductor layer by doping an upper surface of the semiconductor wafer with P-type dopant, and forming a third semiconductor layer by doping the lower surface of the semiconductor wafer exposed by the second contact portion with N-type dopant; forming a first passivation layer on the second semiconductor layer; forming a first contact portion in the first passivation layer; and forming a first electrode inside the first contact portion, and a second electrode inside the second contact portion.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross section view illustrating a related art wafer type solar cell;

FIG. 2 is a cross section view illustrating a wafer type solar cell according to the first embodiment of the present invention;

FIG. 3 is a cross section view illustrating a wafer type solar cell according to the second embodiment of the present invention;

FIG. 4 is a cross section view illustrating a wafer type solar cell according to the third embodiment of the present invention;

FIG. 5 is a cross section view illustrating a wafer type solar cell according to the fourth embodiment of the present invention;

FIGS. 6A to 6E are cross section views illustrating a method for manufacturing a wafer type solar cell according to one embodiment of the present invention;

FIGS. 7A to 7E are cross section views illustrating a method for manufacturing a wafer type solar cell according to another embodiment of the present invention;

FIGS. 8A to 8E are cross section views illustrating a method for manufacturing a wafer type solar cell according to another embodiment of the present invention; and

FIGS. 9A to 9G are cross section views illustrating a method for manufacturing a wafer type solar cell according to another embodiment of the present invention.

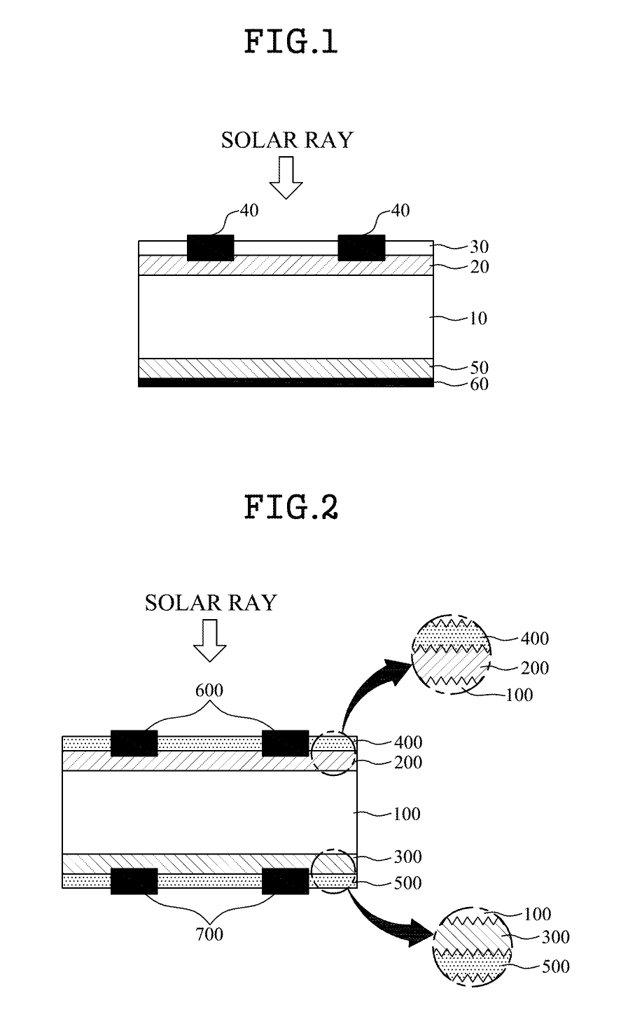

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a wafer type solar cell according to the present invention and a method for manufacturing the same will be described with reference to the accompanying drawings.

FIG. 2 is a cross section view illustrating a wafer type solar cell according to the first embodiment of the present invention.

As shown in FIG. 2, the wafer type solar cell according to the first embodiment of the present invention includes a first semiconductor layer 100, a second semiconductor layer 200, a third semiconductor layer 300, a first passivation layer 400, a second passivation layer 500, a first electrode 600, and a second electrode 700.

The first semiconductor layer 100 is formed of a semiconductor wafer, for example, N-type semiconductor wafer. However, the first semiconductor layer 100 may be formed of a P-type semiconductor wafer.

The second semiconductor layer 200 is formed on one surface of the first semiconductor layer 100, that is, an upper surface of the first semiconductor layer 100, wherein the upper surface of the first semiconductor layer 100 corresponds to a solar ray incidence face. The second semiconductor layer 200 is formed of a P-type semiconductor layer. In the wafer type solar cell of the present invention, the P-type semiconductor layer is formed in the solar ray incidence face, whereby the cell efficiency of the solar cell may be improved owing to enhancement of hole-collecting efficiency.

If the first semiconductor layer 100 is formed of an N-type semiconductor wafer, the second semiconductor layer 200 may be formed of a P-type semiconductor wafer by doping P-type dopant such as boron (B) on an upper surface of the N-type semiconductor wafer. If the first semiconductor layer 100 is formed of a P-type semiconductor wafer, the second semiconductor layer 200 may be formed of a P⁺-type semiconductor wafer by additionally doping the P-type dopant on the upper surface of the P-type semiconductor wafer.

The third semiconductor layer 300 is formed on the other surface of the first semiconductor layer 100, that is, a lower surface of the first semiconductor layer 100, wherein the lower surface of the first semiconductor layer 100 corresponds to an opposite surface to the solar ray incidence face. The third semiconductor layer 300 is formed of an N-type semiconductor layer.

If the first semiconductor layer 100 is formed of the N-type semiconductor wafer, the third semiconductor layer 300 may be formed of an N′-type semiconductor wafer by additionally doping N-type dopant such as phosphorous (P) on a lower surface of the N-type semiconductor wafer. If the first semiconductor layer 100 is formed of the P-type semiconductor wafer, the third semiconductor layer 300 may be formed of an N-type semiconductor wafer by doping the N-type dopant on the lower surface of the P-type semiconductor wafer.

The first passivation layer 400 is formed on the upper surface of the second semiconductor layer 200.

The first passivation layer 400 enables the hole, which is generated by the solar ray, to easily drift toward the first electrode 600 without being lost in the surface of the second semiconductor layer 200. It is preferable that the first passivation layer 400 be formed of a material layer having (−) polarity to attract the hole. Especially, the material layer having (−) polarity may include an oxygen-rich oxide, for example, an oxide including the group III element such as Al₂O₃, Ga₂O₃, or In₂O₃.

The second passivation layer 500 is formed on the lower surface of the third semiconductor layer 300.

The second passivation layer 500 enables the electron, which is generated by the solar ray, to easily drift toward the second electrode 700 without being lost in the surface of the third semiconductor layer 300. It is preferable that the second passivation layer 500 be formed of a material layer having (+) polarity to attract the electron. Especially, the second passivation layer 500 may be formed of an oxygen-deficient oxide material having (+) polarity, for example, an oxide including the group IV element such as SiOx, TiOx, ZrOx, or HfOx. The second passivation layer 500 may be formed of a nitrogen-deficient nitride.

The first electrode 600 is formed in a predetermined pattern to receive the incident solar ray. The first electrode 600 of the predetermined pattern is connected with the second semiconductor layer 200. In more detail, the first electrode 600 is connected with the second semiconductor layer 200 via the first passivation layer 400 from the upper side of the first passivation layer 400. In this case, the first electrode 600 may permeate into a predetermined portion of the second semiconductor layer 200.

In the wafer type solar cell according to the present invention, the first electrode 600, which is provided in the solar ray incidence face, is patterned to allow an area for incidence of the solar ray, whereby transmittance of the solar ray is not deteriorated as compared to the related art.

The second electrode 700 is formed in a predetermined pattern, and is connected with the third semiconductor layer 300. In more detail, the second electrode 700 is connected with the third semiconductor layer 300 via the second passivation layer 500 from the lower side of the second passivation layer 500. In this case, the second electrode 700 may permeate into a predetermined portion of the third semiconductor layer 300.

The second electrode 700, which is provided in the opposite surface to the solar ray incidence face, is patterned similarly to the first electrode 600. Thus, the reflected solar ray may be incident on the rear surface of the solar cell, thereby resulting in the improved cell efficiency of the solar cell.

The first and second electrodes 600 and 700 may be formed of Ag, Al, Cu, Ni, Mn, Sb, Zn, Mo, mixture thereof, or alloy thereof. If needed, each of the first and second electrodes 600 and 700 may be formed in a multi-layered structure of two or more layers of the above metals.

As shown in the drawings, the first semiconductor layer 100 may have an uneven upper surface, whereby the second semiconductor layer 200 and the first passivation layer 400 sequentially formed on the uneven upper surface of the first semiconductor layer 100 also have uneven surfaces. As the first semiconductor layer 100 has an uneven lower surface, the third semiconductor layer 300 and the second passivation layer 500 sequentially formed on the uneven lower surface of the first semiconductor layer 100 also have uneven surfaces. If the first semiconductor layer 100 has the uneven upper or lower surface, the solar ray is refracted or dispersed so that the cell efficiency is improved owing to the increased path of the solar ray.

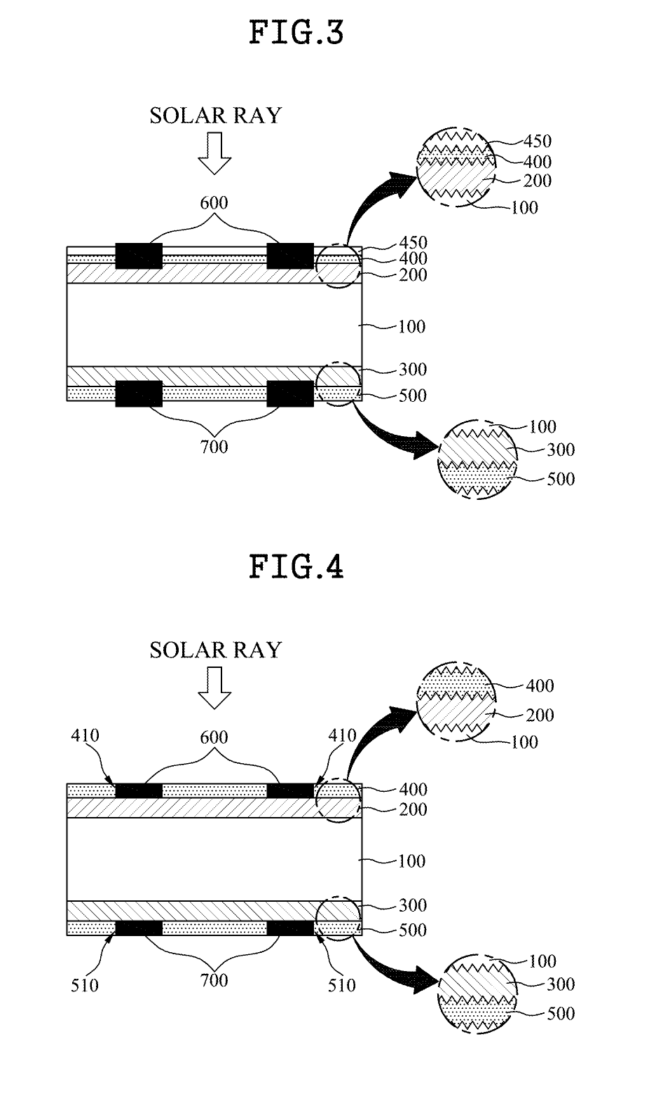

FIG. 3 is a cross section view illustrating a wafer type solar cell according to the second embodiment of the present invention. Except a reflection-preventing layer 450 is additionally formed on a first passivation layer 400, the wafer type solar cell according to the second embodiment of the present invention is identical in structure to the wafer type solar cell according to the first embodiment of the present invention shown in FIG. 2. Thus, the same reference numbers will be used throughout the drawings to refer to the same or like parts as those of the aforementioned embodiment, and the detailed explanation for the same or like parts will be omitted.

As shown in FIG. 3, according to the second embodiment of the present invention, a reflection-preventing layer 450 is formed on a first passivation layer 400.

The reflection-preventing layer 450 prevents reflection of incident solar rays, thereby enhancing absorptivity of the solar rays.

If the reflection-preventing layer 450 is additionally formed on the first passivation layer 400, a first electrode 600 is connected with a second semiconductor layer 200 via the reflection-preventing layer 450 and the first passivation layer 400 from an upper side of the reflection-preventing layer 450.

If the reflection-preventing layer 450 is additionally formed on the first passivation layer 400, the first passivation layer 400 is formed of AlSiOx, preferably. That is, as mentioned above, if the first passivation layer 400 is formed of an oxide including the group III such as Al₂O₃, Ga₂O₃, or In₂O₃, a negative (−) polarity of the first passivation layer 400 may be lost due to hydrogen flowed-in for forming the reflection-preventing layer 450 of SiNx on the first passivation layer 400. Thus, in order to prevent the negative (−) polarity from being lost for the inflow of hydrogen, it is preferable that the first passivation layer 400 be formed of AlSiOx. Even in the above first embodiment of the present invention of FIG. 2, the first passivation layer 400 may be formed of AlSiOx.

FIG. 4 is a cross section view illustrating a wafer type solar cell according to the third embodiment of the present invention. Except that first and second electrodes 600 and 700 are changed in structure, the wafer type solar cell according to the third embodiment of the present invention is identical in structure to the wafer type solar cell according to the first embodiment of the present invention shown in FIG. 2. Thus, the same reference numbers will be used throughout the drawings to refer to the same or like parts as those of the aforementioned embodiment, and the detailed explanation for the same or like parts will be omitted.

As shown in FIG. 4, according to the third embodiment of the present invention, a first electrode 600 is connected with a second semiconductor layer 200 while being provided within a first contact portion 410 in a first passivation layer 400, without penetrating into a predetermined portion of the second semiconductor layer 200 via the first passivation layer 400 from an upper side of the first passivation layer 400.

That is, the first contact portion 410 is formed by removing a predetermined portion of the first passivation layer 400, and the first electrode 600 is formed inside the first contact portion 410. In this structure, the first electrode 600 is not formed on the first passivation layer 400, and does not permeate into the predetermined portion of the second semiconductor layer 200. If case of needed, the first electrode 600 may be formed on the first passivation layer 400.

Similarly, a second electrode 700 is connected with a third semiconductor layer 300 while being provided within a second contact portion 510 in a second passivation layer 500, without penetrating into a predetermined portion of the third semiconductor layer 300 via the second passivation layer 500 from a lower side of the second passivation layer 500.

That is, the second contact portion 510 is formed by removing a predetermined portion of the second passivation layer 500, and the second electrode 700 is formed inside the second contact portion 510. In this structure, the second electrode 700 is not formed under the second passivation layer 500, and does not permeate into the predetermined portion of the third semiconductor layer 300. If case of needed, the second electrode 700 may be formed under the second passivation layer 500.

Although not shown, in the same manner as the above FIG. 3, a reflection-preventing layer may be additionally formed on the first passivation layer 400. In this case, the reflection-preventing layer is also formed on the first contact portion 410, whereby the first electrode 600 is formed inside the first contact portion 410 provided by the first passivation layer 400 and the reflection-preventing layer.

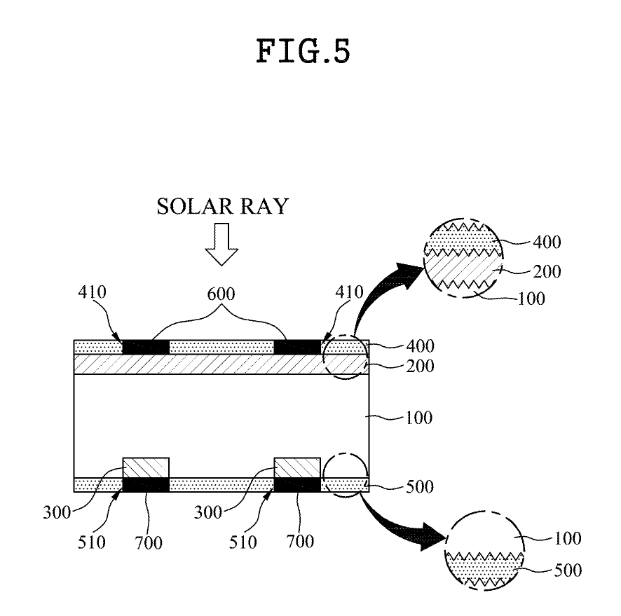

FIG. 5 is a cross section view illustrating a wafer type solar cell according to the fourth embodiment of the present invention.

As shown in FIG. 5, similarly to the above embodiments, the wafer type solar cell according to the fourth embodiment of the present invention includes a first semiconductor layer 100, a second semiconductor layer 200, a third semiconductor layer 300, a first passivation layer 400, a second passivation layer 500, a first electrode 600, and a second electrode 700. Each element is formed of the same material as the above. Hereinafter, the detailed explanation for the same or like parts will be omitted.

As shown in FIG. 5, according to the fourth embodiment of the present invention, a first contact portion 410 is formed in the first passivation layer 400, and the first electrode 600 is connected with the second semiconductor layer 200 while being formed inside the first contact portion 410. Also, a second contact portion 510 is formed in the second passivation layer 500, and the second electrode 700 is connected with the third semiconductor layer 300 while being formed inside the second contact portion 510. Although not shown, a reflection-preventing layer may be additionally formed on the first passivation layer 400, as mentioned above.

The second semiconductor layer 200 is formed on the entire upper surface of the first semiconductor layer 100. The third semiconductor layer 300 is patterned in the predetermined portion of the lower surface of the first semiconductor layer 100, instead of being formed in the entire lower surface of the first semiconductor layer 100. In more detail, the pattern of the third semiconductor layer 300 is provided above the second electrode 700, wherein the pattern of the third semiconductor layer 300 corresponds with the second electrode 700. Between the patterns of the third semiconductor layer 300, there is the first semiconductor layer 100.

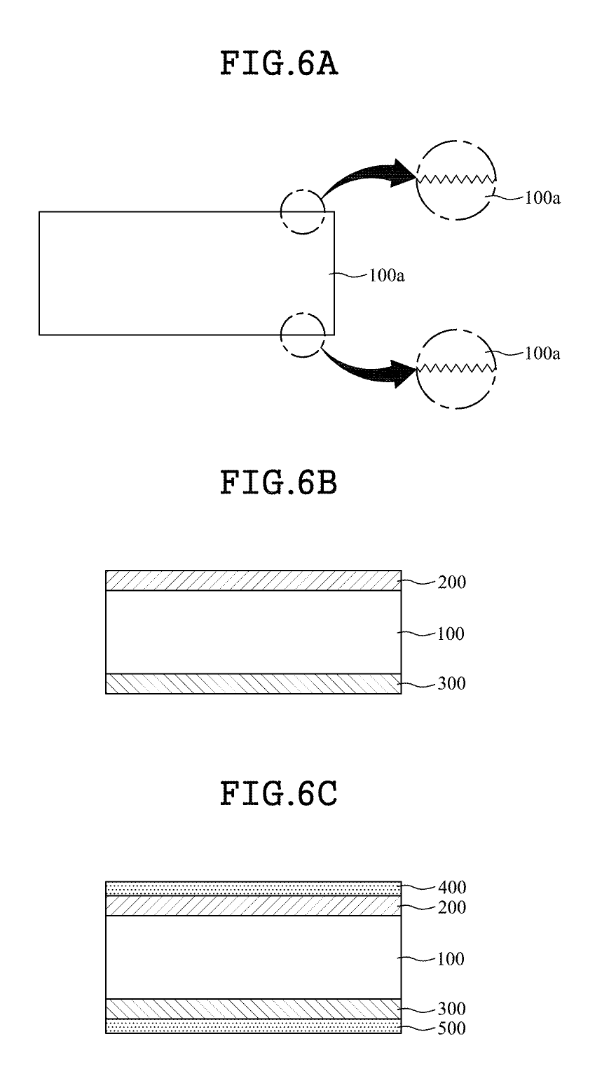

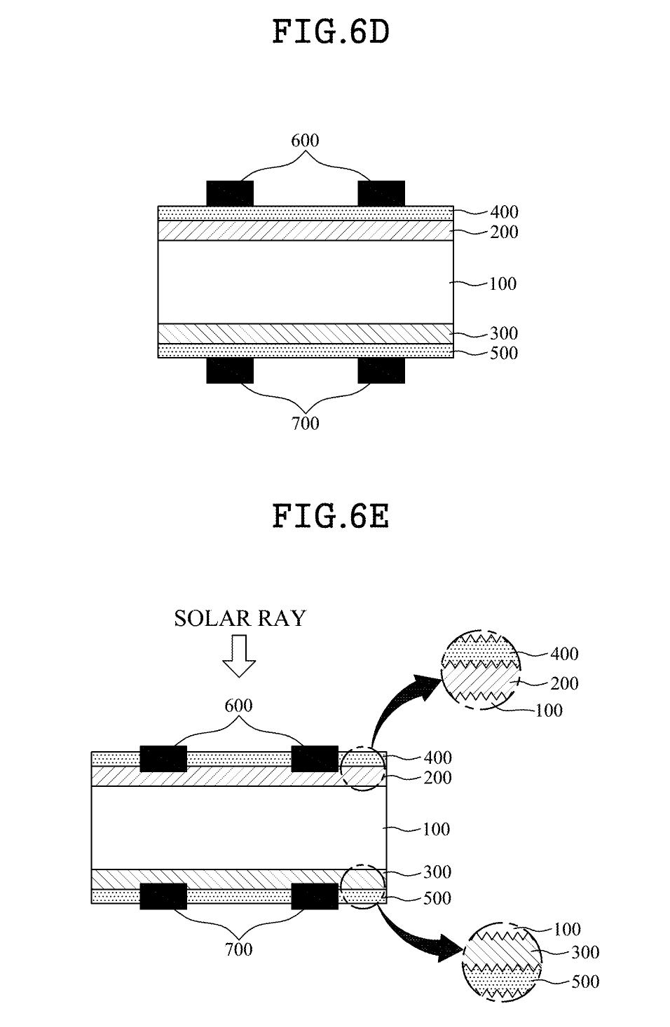

FIGS. 6A to 6E are cross section views illustrating a method for manufacturing the wafer type solar cell according to one embodiment of the present invention, which relate with the wafer type solar cell according to the first embodiment of the present invention shown in FIG. 2.

First, as shown in FIG. 6A, a semiconductor wafer 100a is prepared.

A process for preparing the semiconductor wafer 100a includes manufacturing P-type or N-type semiconductor wafer 100a, and forming uneven lower and/or upper surface in the semiconductor wafer 100a.

The semiconductor wafer 100a may use monocrystalline silicon or polycrystalline silicon. The monocrystalline silicon has high purity and low crystal defect density, whereby the monocrystalline silicon enhances the cell efficiency of the solar cell. However, since the monocrystalline silicon is high-priced, the economical efficiency of the solar cell is deteriorated. Meanwhile, in comparison to the monocrystalline silicon, the efficiency of the polycrystalline silicon is relatively low. However, the polycrystalline silicon enables to lower the manufacturing cost by using low-priced materials and processes, whereby the polycrystalline silicon is appropriate for the mass production.

It is possible to make the lower and/or upper surface of the semiconductor wafer 100a uneven by etching. If using the monocrystalline silicon for the semiconductor wafer 100a, the uneven surface may be formed by alkali-etching. If using the polycrystalline silicon for the semiconductor wafer 100a, it is difficult to form the uneven surface by alkali-etching because many crystal grains are oriented at different directions. In order to obtain the uneven surface in the semiconductor wafer 100a of the polycrystalline silicon, it is preferable to perform reactive ion etching (RIE), isotropic etching using acid solution, or mechanical etching.

The RIE enables the uniform formation of uneven surface in the semiconductor wafer 100a without regard to the crystal orientation of crystal grains. Thus, the RIE can be applied to the procedure for forming the uneven surface of polycrystalline silicon wafer. Especially, if applying the RIE, the following processes may be performed in the same chamber. The RIE uses a main gas as Cl₂, SF₆, NF₃, HBr, or mixture thereof, and an additional gas as Ar, O₂, N₂, He, or mixture thereof.

As shown in FIG. 6B, the lower and upper surfaces of the semiconductor wafer 100a are doped with a predetermined dopant, thereby forming a first semiconductor layer 100, a second semiconductor layer 200, and a third semiconductor layer 300.

That is, the upper surface of the semiconductor wafer 100a is doped with the predetermined dopant, and more detail, P-type dopant, thereby forming the second semiconductor layer 200. The lower surface of the semiconductor wafer 100a is doped with the predetermined dopant, and more detail, N-type dopant, thereby forming the third semiconductor layer 300. In this case, the remaining semiconductor wafer 100a between the second and third semiconductor layers 200 and 300 forms the first semiconductor layer 100.

A process for forming the second semiconductor layer 200 may be carried out by a plasma ion-doping method. In more detail, this process may include supplying P-type dopant gas such as B₂H₆ to the upper surface of the semiconductor wafer 100a at a plasma atmosphere. After carrying out the plasma ion-doping process, the doped ion may function as impurity. Thus, it is preferable that a heat treatment for heating the doped ion to an appropriate temperature be carried out to activate the doped ion and to bond the activated ion to Si.

A process for forming the third semiconductor layer 300 may be carried out by a plasma ion-doping method. In more detail, this process may include supplying N-type dopant gas such as PH₃ to the lower surface of the semiconductor wafer 100a at a plasma atmosphere. In the same manner as the above, a heat treatment is carried out after the plasma ion-doping process, preferably.

There is no predetermined sequential order in the process for forming the second semiconductor layer 200 and the process for forming the third semiconductor layer 300.

As shown in FIG. 6C, a first passivation layer 400 is formed on the second semiconductor layer 200, and a second passivation layer 500 is formed on the third semiconductor layer 300.

The first passivation layer 400 may be formed of a material layer having (−) polarity, for example, oxygen-rich oxide including the group III element such as AlSiOx, Al₂O₃, Ga₂O₃, or In₂O₃, by plasma CVD.

The second passivation layer 500 may be formed of a material layer having (+) polarity, for example, oxygen-deficient oxide including the group IV element such as SiOx, TiOx, ZrOx, or HfOₓ, or nitrogen-deficient nitride such as SiNₓ.

There is no predetermined sequential order in the process for forming the first passivation layer 400 and the process for forming the second passivation layer 500.

As shown in FIG. 6D, the first electrode 600 is patterned on the first passivation layer 400, and the second electrode 700 is patterned on the second passivation layer 500.

Respective processes for forming the first electrode 600 and the second electrode 700 may use Ag, Al, Cu, Ni, Mn, Sb, Zn, Mo, mixture thereof, or alloy thereof by printing process.

In this case, the printing process may be a screen printing method, an inkjet printing method, a gravure printing method, a gravure offset printing method, a reverse printing method, a flexo printing method, or a microcontact printing method. In case of the screen printing method, ink is coated onto a screen, and then the squeegee is moved on the screen coated with the ink while being pressed-down, whereby the ink is printed through a mesh of the screen. The inkjet printing method is a printing method in which tiny ink drops collide with a substrate. The gravure printing method is carried out by removing ink from an ink non-coated portion with a flat surface by the use of doctor blade, and transferring ink from an etched ink-coated portion with a hollow shape to a substrate. The gravure offset printing method is carried out by transferring ink from a printing plate to a blanket, and again transferring ink from the blanket to a substrate. The reverse printing method is a printing method using ink as a solvent. The flexo printing method is a printing method which uses ink coated onto a relief portion. The microcontact printing method is an imprinting method which uses a stamp with a desired material.

If using the printing process, the first electrode 600 or second electrode 700 may be patterned in a predetermined shape by one process, whereby the process is simplified.

Meanwhile, if the first electrode 600 or second electrode 700 is formed in a multi-layered structure including two or more layers, an electroplating process may be used.

There is no predetermined sequential order in the process for patterning the first electrode 600 and the process for patterning the second electrode 700.

As shown in FIG. 6E, a heat treatment is carried out so that the first electrode 600 is connected with the second semiconductor layer 200, and the second electrode 700 is connected with the third semiconductor layer 300, thereby completing the wafer type solar cell.

That is, if carrying out the heat treatment at a high temperature above 850° C., the electrode material of the first electrode 600 permeates into the second semiconductor layer 200 via the first passivation layer 400, whereby the first electrode 600 is connected with the second semiconductor layer 200.

By the heat treatment, the electrode material of the second electrode 700 permeates into the third semiconductor layer 300 via the second passivation layer 500, whereby the second electrode 700 is connected with the third semiconductor layer 300.

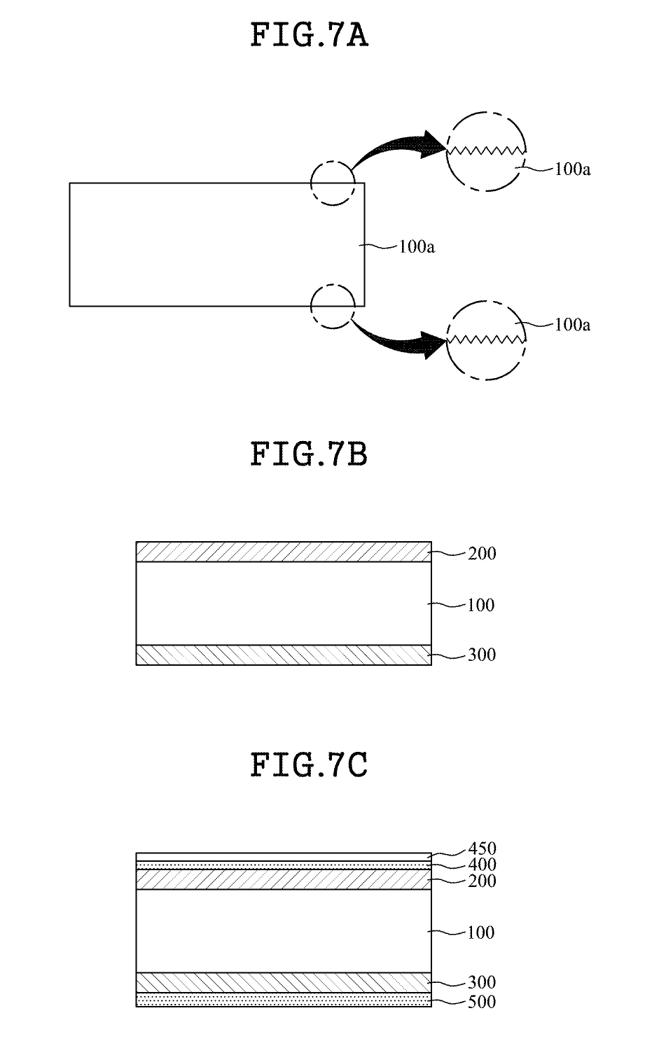

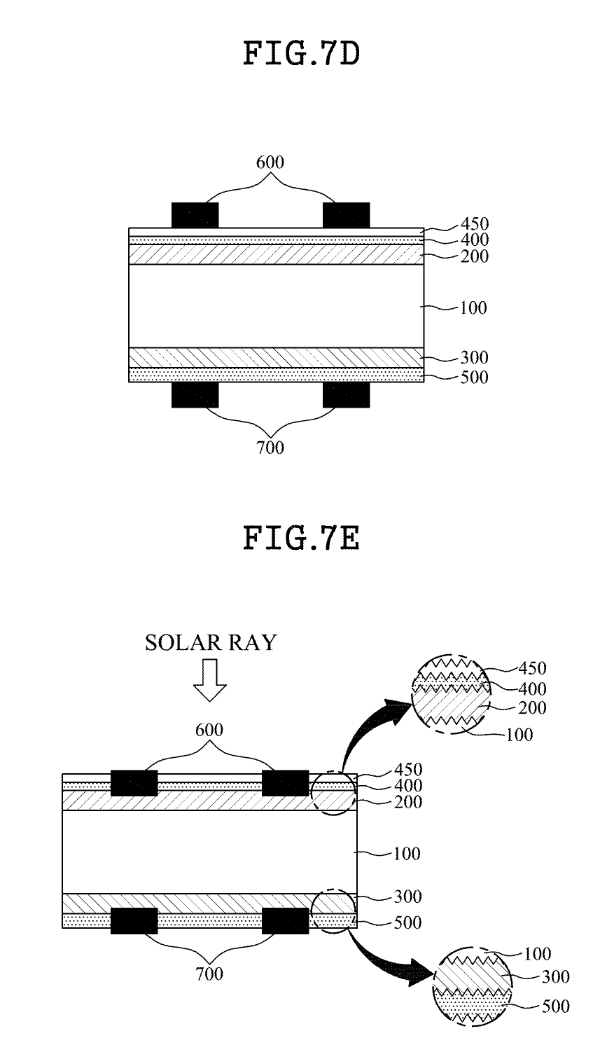

FIGS. 7A to 7E are cross section views illustrating a method for manufacturing the wafer type solar cell according to another embodiment of the present invention, which relate with the wafer type solar cell according to the second embodiment of the present invention shown in FIG. 3. Hereinafter, the detailed explanation for the same parts as those of the above embodiment will be omitted.

First, as shown in FIG. 7A, a semiconductor wafer 100a is prepared.

As shown in FIG. 7B, a second semiconductor layer 200 is formed by doping an upper surface of the semiconductor wafer 100a with P-type dopant, and a third semiconductor layer 300 is formed by doping a lower surface of the semiconductor wafer 100 with N-type dopant. In this case, the remaining semiconductor wafer 100a between the second and third semiconductor layers 200 and 300 forms a first semiconductor layer 100.

As shown in FIG. 7C, a first passivation layer 400 and a reflection-preventing layer 450 are sequentially formed on the second semiconductor layer 200, and a second passivation layer 500 is formed on the third semiconductor layer 300.

Preferably, the first passivation layer 400 may be formed of AlSiOx by plasma CVD, and the reflection-preventing layer 450 may be formed of SiNx by plasma CVD.

As shown in FIG. 7D, a first electrode 600 is patterned on the reflection-preventing layer 450, and a second electrode 700 is patterned on the second passivation layer 500.

As shown in FIG. 7E, a heat treatment is carried out so that the first electrode 600 is connected with the second semiconductor layer 200, and the second electrode 700 is connected with the third semiconductor layer 300, thereby completing the wafer type solar cell.

That is, as the heat treatment enables the electrode material of the first electrode 600 to permeate into the second semiconductor layer 200 via the reflection-preventing layer 450 and the first passivation layer 400, and also enables the electrode material of the second electrode 700 to permeate into the third semiconductor layer 300 via the second passivation layer 500.

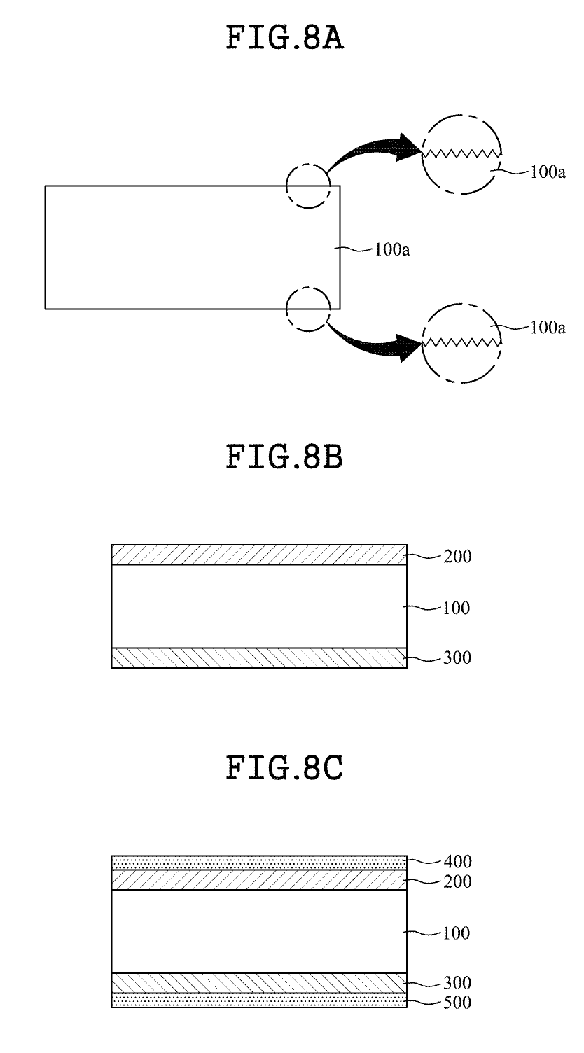

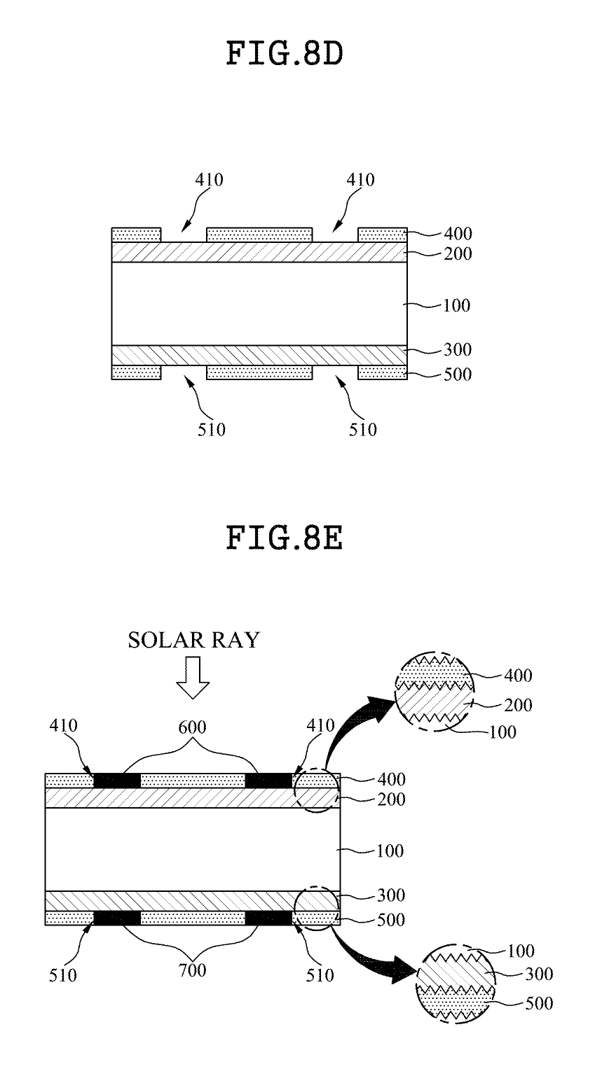

FIGS. 8A to 8E are cross section views illustrating a method for manufacturing the wafer type solar cell according to another embodiment of the present invention, which relate with the wafer type solar cell according to the third embodiment of the present invention shown in FIG. 4. Hereinafter, the detailed explanation for the same parts as those of the above embodiment will be omitted.

First, as shown in FIG. 8A, a semiconductor wafer 100a is prepared.

As shown in FIG. 8B, a second semiconductor layer 200 is formed by doping an upper surface of the semiconductor wafer 100a with P-type dopant, and a third semiconductor layer 300 is formed by doping a lower surface of the semiconductor wafer 100a with N-type dopant. In this case, the remaining semiconductor wafer 100a between the second and third semiconductor layers 200 and 300 forms a first semiconductor layer 100.

As shown in FIG. 8C, a first passivation layer 400 is formed on the second semiconductor layer 200, and a second passivation layer 500 is formed on the third semiconductor layer 300.

As shown in FIG. 8D, a first contact portion 410 having a predetermined pattern is formed in the first passivation layer 400, and a second contact portion 510 having a predetermined pattern is formed in the second passivation layer 500.

The first and second contact portions 410 and 510 may be formed by an etching process using a predetermined mask.

As shown in FIG. 8E, a first electrode 600 is formed inside the first contact portion 410, and a second electrode 700 is formed inside the second contact portion 510, thereby completing the wafer type solar cell.

The first electrode 600 is connected with the second semiconductor layer 200 while being formed inside the first contact portion 410, and the second electrode is connected with the third semiconductor layer 300 while being formed inside the second contact portion 510.

The first and second electrodes 600 and 700 may be formed by a printing process or electroplating process. In this case, the first electrode 600 does not permeate into the second semiconductor layer 200, and the second electrode 700 does not permeate into the third semiconductor layer 300.

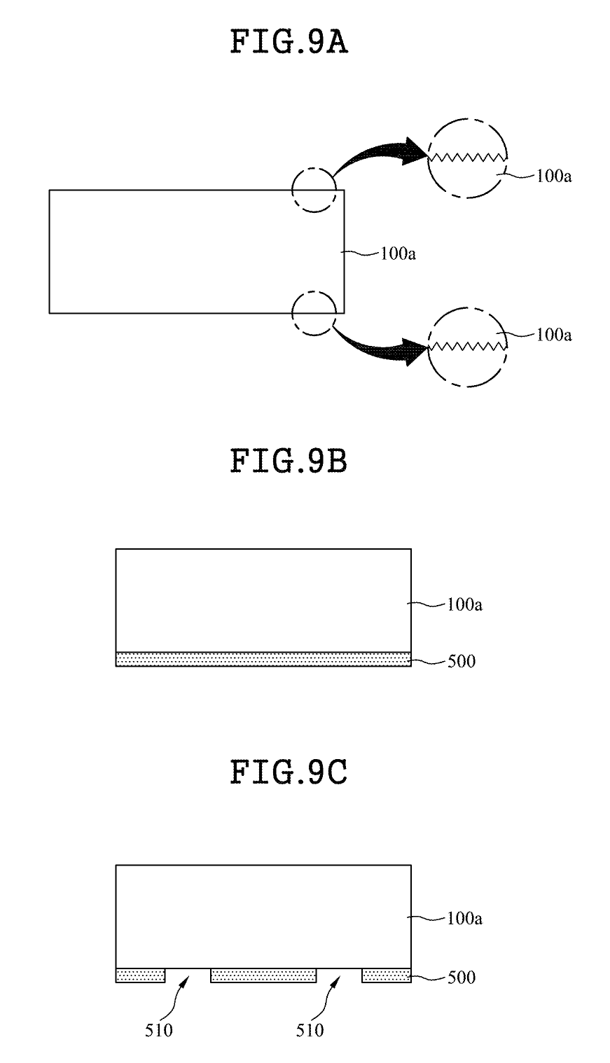

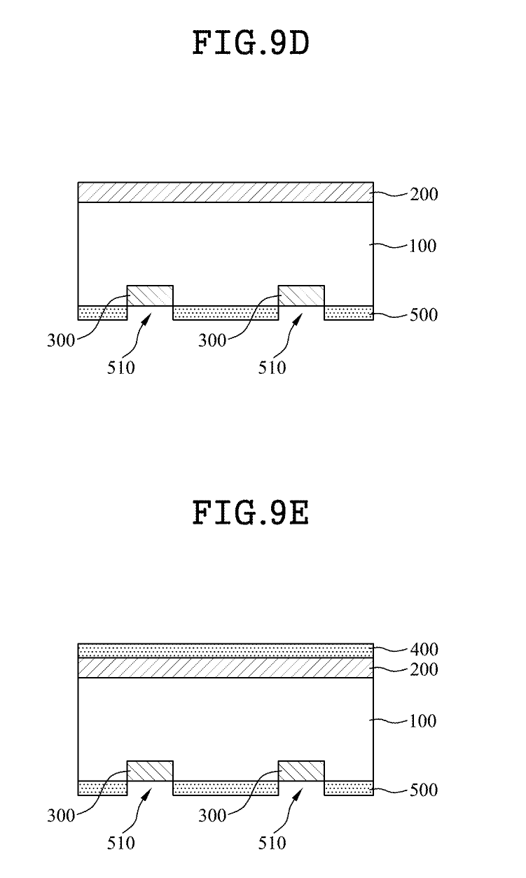

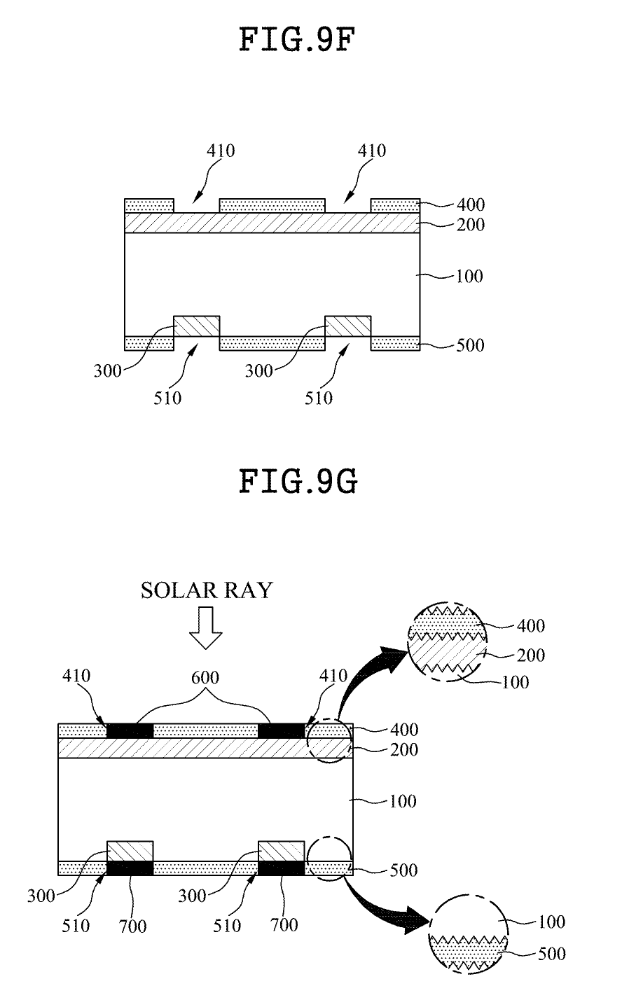

FIGS. 9A to 9G are cross section views illustrating a method for manufacturing the wafer type solar cell according to another embodiment of the present invention, which relate with the wafer type solar cell according to the fourth embodiment of the present invention shown in FIG. 5. Hereinafter, the detailed explanation for the same parts as those of the above embodiment will be omitted.

First, as shown in FIG. 9A, a semiconductor wafer 100a is prepared.

As shown in FIG. 9B, a second passivation layer 500 is formed on a lower surface of the semiconductor wafer 100a.

As shown in FIG. 9C, a second contact portion 510 having a predetermined pattern is formed in the second passivation layer 500.

As shown in FIG. 9D, an upper surface of the semiconductor wafer 100a is doped with P-type dopant, thereby forming a second semiconductor layer 200. The lower surface of the semiconductor wafer 100a, and more particularly, the lower surface of the semiconductor wafer 100a exposed by the second contact portion 510 is doped with N-type dopant, thereby forming a third semiconductor layer 300.

In this case, the remaining semiconductor wafer 100a between the second and third semiconductor layers 200 and 300 forms a first semiconductor layer 100.

In more detail, the third semiconductor layer 300 corresponds to the pattern of the second contact portion 510. Between the patterns of the third semiconductor layer 300, there is the first semiconductor layer 100.

As shown in FIG. 9E, a first passivation layer 400 is formed on the second semiconductor layer 200.

As shown in FIG. 9F, a first contact portion having a predetermined pattern is formed in the first passivation layer 400.

As shown in FIG. 9G, a first electrode 600 is formed inside the first contact portion 410, and a second electrode 700 is formed inside the second contact portion 510, thereby completing the wafer type solar cell.

Accordingly, in the wafer type solar cell according to the present invention, the P-type semiconductor layer is formed by doping the additional P-type dopant, instead of using the electrode material. Thus, the P-type semiconductor layer is formed in the solar ray incidence face, thereby resulting in the improved hole-collecting efficiency. Also, the first electrode is patterned in the solar ray incidence face, thereby improving the cell efficiency.

Especially, if forming the P-type semiconductor layer by doping the additional P-type dopant, the first passivation layer is formed so as to make the hole easily drift toward the first electrode without being lost in the surface of the P-type semiconductor layer, thereby preventing the cell efficiency from being lowered.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A solar cell comprising:
a semiconductor wafer having a first semiconductor layer;
a second semiconductor layer doped with P-type dopant on one surface of the first semiconductor layer;
a third semiconductor layer doped with N-type dopant on an opposed surface of the first semiconductor layer;
a first passivation layer on the second semiconductor layer;
a second passivation layer on the third semiconductor layer;
a first electrode electrically connected with the second semiconductor layer; and
a second electrode electrically connected with the third semiconductor layer.

2. The solar cell according to claim 1, wherein the first passivation layer comprises a material layer having (−) polarity for attracting holes, so that holes generated by a solar ray drift toward the first electrode without being lost in the second semiconductor layer or on a surface of the second semiconductor layer.

3. The solar cell according to claim 2, wherein the first passivation layer includes oxygen-rich oxide.

4. The solar cell according to claim 1, wherein the second passivation layer comprises a material layer having (+) polarity for attracting electrons so that electrons generated by a solar ray drift toward the second electrode without being lost in the third semiconductor layer or on a surface of the third semiconductor layer.

5. The solar cell according to claim 4, wherein the second passivation layer comprises oxygen-deficient oxide or nitrogen-deficient nitride.

6. The solar cell according to claim 1, wherein the first and second electrodes are patterned to receive an incident solar ray.

7. The solar cell according to claim 1, wherein the first electrode contacts the second semiconductor layer through the first passivation layer, and the second electrode contact the third semiconductor layer through the second passivation layer.

8. The solar cell according to claim 1, wherein the first electrode is inside a first contact portion in the first passivation layer, and the second electrode is inside a second contact portion in the second passivation layer.

9. The solar cell according to claim 1, wherein a reflection-preventing layer is additionally on the first passivation layer.

10. The solar cell according to claim 9, wherein the first passivation layer comprises AlₐSi_{b}Oₓ, where a and b are each >0 and (3a/2+3b/2)<x≦(3a/2+2b) and the reflection-preventing layer comprises Si_{y}N_{z}, where an atomic ratio of y to z is greater than 3:4, but less than or equal to 3:2.

11. The solar cell according to claim 1, wherein the second semiconductor layer is on entire portions of one surface of the first semiconductor layer, and the third semiconductor layer is patterned on a predetermined portion of the opposed surface of the first semiconductor layer.

12. The solar cell according to claim 11, wherein the first semiconductor layer is between adjacent patterns of the third semiconductor layer.

13. The solar cell according to claim 1, wherein the first semiconductor layer has an uneven lower or upper surface.

14. A method for manufacturing a solar cell comprising:
doping a surface of a semiconductor wafer having a first semiconductor layer with P-type dopant to form a second semiconductor layer;
doping an opposed surface of the semiconductor wafer with N-type dopant to form a third semiconductor layer;
forming a first passivation layer on the second semiconductor layer;
forming a second passivation layer on the third semiconductor layer;
forming a first electrode electrically connected with the second semiconductor layer; and
forming a second electrode electrically connected with the third semiconductor layer.

15. The method according to claim 14,
wherein forming the first electrode includes: patterning the first electrode on the first passivation layer, and applying a heat treatment to cause a material of the first electrode to permeate into the second semiconductor layer, and
forming the second electrode includes: patterning the second electrode on the second passivation layer, and applying a heat treatment to cause a material of the second electrode to permeate into the third semiconductor layer.

16. The method according to claim 14,
wherein forming the first electrode includes: forming a first contact portion having a predetermined pattern in the first passivation layer, and forming the first electrode inside the first contact portion, and
forming the second electrode includes: forming a second contact portion having a predetermined pattern in the second passivation layer, and forming the second electrode inside the second contact portion.

17. The method according to claim 14, further comprising forming a reflection-preventing layer on the first passivation layer between forming the first passivation layer and forming the first electrode.

18. A method for manufacturing a solar cell comprising:
forming a lower passivation layer on a first surface of a semiconductor wafer, the semiconductor wafer having a first semiconductor layer;
forming a lower contact portion in the lower passivation layer;
doping a second surface of the semiconductor wafer with P-type dopant to form a second semiconductor layer;
doping the first surface of the semiconductor wafer exposed by the second contact portion with N-type dopant to form a third semiconductor layer;
forming an upper passivation layer on the second semiconductor layer;
forming an upper contact portion in the upper passivation layer; and
forming a first electrode inside the upper contact portion, and a second electrode inside the lower contact portion.

19. The method according to claim 18, wherein the semiconductor wafer includes a P-type or N-type semiconductor wafer; and the method further comprises forming an uneven structure in one of the first surface or the second surface of the semiconductor wafer.

20. The method according to claim 18,
wherein forming the second semiconductor layer includes: supplying P-type dopant gas to a first plasma to dope the second surface of the semiconductor wafer with P-type dopant; and applying a heat treatment to active the P-type dopant, and
wherein forming the third semiconductor layer includes: supplying N-type dopant gas to a second plasma to dope the first surface of the semiconductor wafer with N-type dopant; and applying a heat treatment to active the N-type dopant.
